(19) United States
(12) Patent Application Publication
(10) Pub. No.: US 2008/0057645 A1
(43) Pub. Date: Mar. 6, 2008

(54) FABRICATING METHOD OF MOSFET WITH THICK GATE DIELECTRIC LAYER

(75) Inventors: Chrong-Jung Lin, Taipei County (TW); Hsin-Ming Chen, Tainan County (TW); Ya-Chin King, Taoyuan County (TW)

Correspondence Address: J C PATENTS, INC., 4 VENTURE, SUITE 250, IRVINE, CA, 92618, US

(73) Assignee: eMEMORY TECHNOLOGY INC., Hsin-Chu (TW)

(21) Appl. No.: 11/831,443

(22) Filed: Jul. 31, 2007

Related U.S. Application Data
(60) Provisional application No. 60/824,604, filed on Sep. 5, 2006.

(51) Int. Cl. H01L 21/336

(52) U.S. Cl. 438/257; 257/E21.409

(57) ABSTRACT

The fabricating method of a thick gate dielectric layer transistor is disclosed. A substrate including a first and a second regions and isolation structures is provided. A pad layer and a masking layer are formed on the substrate between the isolation structures. After the masking layer and the pad layer in the second region are removed, a dielectric layer and a conductive layer are sequentially formed on the substrate. The conductive layer, the dielectric layer and the pad layer are patterned to form a first gate structure in the first region and a second gate structure in the second region. A first source region and a first drain region are respectively formed in the substrate adjacent to the first gate structure, and a second source region and a second drain region are formed respectively in the substrate adjacent to the second gate structure.

### CROSS-REFERENCE TO RELATED APPLICATION

This application claims the priority benefit of U.S. Provisional Application Ser. No. 60/824,604, filed on Sep. 5, 2006. All disclosure of the U.S. provisional application is incorporated herein by reference.

### BACKGROUND OF THE INVENTION

1. Field of the Invention

The present invention relates to a method of fabricating a semiconductor device, more specifically, to a method of fabricating a non-volatile memory.

2. Description of Related Art

When the semiconductor process develops into the deep sub-micron fabricating process, the size of a device gets smaller and smaller. For the memory device, it indicates that the size of a memory cell also gets smaller and smaller. In the other aspect, as the amount of data that information electronic products (such as computers, cellular phones, digital cameras or personal digital assistants (PDA)) need to process and store keeps increasing, the memory capability required in these information electronic products gets larger and larger accordingly. Faced with the formidable demand for memory devices of smaller sizes with larger memory capability, producing small-sized, highly-integrated memory devices with fine quality is the common goal shared by the industry.

With its advantage of safeguarding the written data even after the power to the non-volatile memory device is cut off, the non-volatile memory device has become a memory device widely used in personal computers and electronic equipments.

A typical non-volatile memory device has a stacked structure constituted by a floating gate and a control gate manufactured by doped polysilicon. A dielectric layer is disposed respectively between the floating gate and the substrate and between the floating gate and the control gate.

However, the non-volatile memory needs to form a plurality of polysilicon layers and a plurality of dielectric layers. During the fabricating process, it goes through a plurality of mask procedures, which elongates the fabricating process and increases the fabricating cost.

U.S. Pat. No. 6,678,190 discloses a non-volatile memory, which does not require a plurality of polysilicon layers to be formed and instead uses two serially connected P-type metal-oxide-semiconductor (MOS) transistors disposed on the N well as the select transistor and the floating gate transistor. Since no control gate needs to be formed, the fabricating process of the non-volatile memory can be integrated with that of the complementary MOS transistor thereby reducing the fabricating cost.

However, the floating gate transistor and an input/output (I/O) transistor of the peripheral circuit region are manufactured by the same fabricating process. The thickness of a tunneling dielectric layer in the floating gate transistor is the same as that of a gate dielectric layer of the I/O transistor in the peripheral circuit region. With the increased integration level of the integrated circuit and the shrinking size of the device, the size of the I/O transistor and the floating gate transistor also gets smaller. Hence, the thicknesses of the gate dielectric layer in the I/O transistor and the tunneling dielectric layer in floating gate transistor get thinner as well. Taking the 1.2/2.5V fabricating process of the 90 nanometer semiconductor technology in the leading foundry company, Taiwan Semiconductor Manufacturing Company Limited as an example, the thickness of the gate dielectric layer is at most 50 angstroms (Å). When charges exist in the floating gate, if the thickness of the tunneling dielectric layer is not thick enough, the charges stored in the floating gate are very easy to leak into the substrate, which results in a worsened capacity of the floating gate for storing charges thereby affecting the reliability of the memory. As indicated in relevant publications, reliable non-volatile memory devices (floating gate technologies) require a tunneling dielectric layer with a thickness at least more than 70 angstroms (Å). In other words, a thin tunneling dielectric layer is a major weakness for the floating-gate type non-volatile memory device, especially in terms of the long-term reliability for storing charges.

If the thickness of the tunneling dielectric layer is to be increased, one more photomask procedure is required, which heavily influences the thermal budget of the whole fabricating process resulting in both the whole fabricating process and the device deviating from the original designated values. It takes a very long time and a great investment to work out a solution in vain for a simple embedded non-volatile memory.

Moreover, the thickness of a semiconductor device provided by the advanced fabricating process is usually not very thick and the advanced fabricating process cannot provide suitable high-voltage devices for withstanding the high-voltage operations (such as more than 7V) performed on the non-volatile memory device. One of the important reasons is that the thickness of a thin logic device gate dielectric layer manufactured by the advanced fabricating process renders the device unable to withstand a high gate voltage. Similarly, if a suitable high-voltage device is to be provided, the thickness of the gate dielectric layer necessarily has to be increased, the number of photomask procedures substantially increased, the whole thermal budget of the fabricating process also significantly raised, which result in that both the whole fabricating process and the device deviate from the original designated values. It would take a very long time and a great investment for researching and developing but in vain; the outcome cannot serve as a solution to the problem of the simple embedded non-volatile memory.

### SUMMARY OF THE INVENTION

The present invention relates to a metal-oxide-semiconductor field effect transistor (MOSFET) with a thick gate dielectric layer, more specifically to a fabricating method of a non-volatile memory, wherein without increasing the complexity of the fabricating process and raising the thermal budget, the thickness of a tunneling dielectric layer in a floating gate transistor is increased and the thickness of a gate dielectric layer in an input/output (I/O) transistor can be increased simultaneously to withstand a higher operational voltage.

The fabricating method of an MOSFET with a thick gate dielectric layer is disclosed by the invention includes the following steps. First, a substrate including a first region and a second region is provided, and a plurality of isolation structures has already been formed in the substrate. An insulating medium serving as a pad layer for Shallow Trench Isolation module or a buffering layer for well implantation process and a masking layer are sequentially formed on the substrate among each of the isolation structures. After patterning the masking layer, the insulating medium in the second region is also removed. The masking layer is removed. Afterwards, a dielectric layer and a conductive layer are sequentially formed on the substrate. The conductive layer, the dielectric layer and the insulating medium are patterned so as to form a first gate structure in the first region and a second gate structure in the second region. A first source region and a first drain region are respectively formed in the substrate at the two sides of the first gate structure. A second source region and a second drain region are respectively formed in the substrate at the two sides of the second gate structure.

According to the fabricating method of an MOSFET with a thick gate dielectric layer described in one preferred embodiment of the invention, the first region is a memory cell region and the second region is a peripheral circuit region.

According to the fabricating method of an MOSFET with a thick gate dielectric layer transistor described in one preferred embodiment of the invention, the first gate structure, the first source region and the first drain region constitute a floating gate transistor having the characteristics of a non-volatile memory device. The second gate structure, the second source region and the second drain region constitute either input/output (I/O) or logic transistor.

According to the fabricating method of an MOSFET with a thick gate dielectric layer described in one preferred embodiment of the invention, the insulating medium and the dielectric layer form a tunneling dielectric layer of the floating gate transistor.

According to the fabricating method of a thick gate dielectric layer transistor described in one preferred embodiment of the invention, the dielectric layer forms a gate dielectric layer of the I/O or logic transistor.

According to the fabricating method of an MOSFET with a thick gate dielectric layer described in one preferred embodiment of the invention, the thickness of the dielectric layer is smaller than that of the insulating medium.

According to the fabricating method of an MOSFET with a thick gate dielectric layer described in one preferred embodiment of the invention, the material of the conductive layer includes doped polysilicon.

According to the fabricating method of an MOSFET with a thick gate dielectric layer described in one preferred embodiment of the invention, removing the insulating medium in the second region includes the following steps. A patterned photoresist layer is formed on the substrate to cover the first region. The patterned photoresist layer is used as a mask to remove a portion of the insulating medium.

According to the fabricating method of an MOSFET with a thick gate dielectric layer described in one preferred embodiment of the invention, the material of the insulating medium includes silicon oxide.

According to the fabricating method of an MOSFET with a thick gate dielectric layer described in one preferred embodiment of the invention, the material of the dielectric layer includes silicon oxide.

According to the fabricating method described in one preferred embodiment of the invention, the floating gate may also be connected with a conductive layer and thus becomes a non-floating-gate so as to form the transistor of a thicker gate dielectric layer (MOS device).

The fabricating method of an MOSFET with a thick gate dielectric layer disclosed by the invention includes the following steps. First, a substrate including a first region, a second region and third region is provided, and a plurality of isolation structures has already been formed in the substrate. An insulating medium serving as a pad layer for STI module or a buffering layer for well implantation process and a masking layer are sequentially formed on the substrate among each of the isolation structures. After patterning the masking layer, the insulating medium in the second region and the third region is also removed. The masking layer is removed. A first dielectric layer is formed on the substrate. The first dielectric layer in the third region is removed. A second dielectric layer is formed on the substrate. A conductive layer is formed on the substrate. The conductive layer, the second dielectric layer, the first dielectric layer and the insulating medium are patterned so as to form a first gate structure in the first region, a second gate structure in the second region and a third gate structure in the third region. A first source region and a first drain region are respectively formed in the substrate at the two sides of the first gate structure. A second source region and a second drain region are respectively formed in the substrate at the two sides of the second gate structure. A third source region and a third drain region are respectively formed in the substrate at the two sides of the third gate structure.

According to the fabricating method of an MOSFET with a thick gate dielectric layer described in one preferred embodiment of the invention, the first gate structure, the first source region and the first drain region constitute the floating gate transistor having the characteristics of a non-volatile memory device. The second gate structure, the second source region and the second drain region constitute a first I/O transistor. The third gate structure, the third source region and the third drain region constitute a second I/O transistor.

According to the fabricating method of an MOSFET with a thick gate dielectric layer described in one preferred embodiment of the invention, the insulating medium, the first dielectric layer and the second dielectric layer constitute a tunneling dielectric layer of the floating gate transistor.

According to the fabricating method of an MOSFET with a thick gate dielectric layer transistor described in one preferred embodiment of the invention, the first dielectric layer and the second dielectric layer constitute a gate dielectric layer of the first I/O transistor.

According to the fabricating method of an MOSFET with a thick gate dielectric layer described in one preferred embodiment of the invention, the second dielectric layer forms a gate dielectric layer of the second I/O transistor.

According to the fabricating method of an MOSFET with a thick gate dielectric layer described in one preferred embodiment of the invention, the thickness of the second dielectric layer is smaller than that of the first dielectric layer and the thickness of the first dielectric layer is smaller than that of the insulating medium.

According to the fabricating method of an MOSFET with a thick gate dielectric layer described in one preferred embodiment of the invention, the material of the conductive layer includes doped polysilicon.

According to the fabricating method of an MOSFET with a thick gate dielectric layer transistor described in one preferred embodiment of the invention, removing the insulating medium in the second region and the third region includes the following steps. A first patterned photoresist layer is formed on the substrate to cover the first region. The patterned photoresist layer is used as a mask to remove a portion of the exposed insulating medium.

According to the fabricating method of an MOSFET with a thick gate dielectric layer described in one preferred embodiment of the invention, removing the first dielectric layer in the third region includes the following steps. A second patterned photoresist layer is formed on the substrate to cover the first and the second regions. The second patterned photoresist layer is used as a mask to remove a portion of the exposed first dielectric layer.

According to the fabricating method of an MOSFET with a thick gate dielectric layer described in one preferred embodiment of the invention, the material of the insulating medium, the first dielectric layer and the second dielectric layer includes silicon oxide.

According to the fabricating method of an MOSFET with a thick gate dielectric layer described in one preferred embodiment of the invention, the floating gate may also be connected with a conductive layer and thus turned into a non-floating-gate so as to form a transistor with a thicker gate dielectric layer (MOS device).

In the fabricating method of the MOSFET with a thick gate dielectric layer disclosed by the invention, the tunneling dielectric layer of the floating gate transistor is constituted by the insulating medium and one or more than one dielectric layers, and the thickness of the tunneling dielectric layer is larger than 110 angstroms. Therefore, a better capacity for storing charges can be obtained.

In the fabricating method of the MOSFET with a thick gate dielectric layer disclosed by the invention, a portion of the insulating medium is retained as a portion of the tunneling dielectric layer. Hence, a floating gate transistor having a thicker tunneling dielectric layer can be fabricated without changing the fabricating conditions (especially the complexity and the thermal budget of the fabricating process).

In the fabricating method of the MOSFET with a thick gate dielectric layer disclosed by the invention, the damage done to the insulating medium during the removal of the masking layer can be repaired when the dielectric layer grows at a high temperature or when a source/drain is formed by an annealing process. Accordingly, without increasing the complexity and the thermal budget of the fabricating process, the thickness of the tunneling dielectric layer of the floating gate transistor is increased so as to improve the capacity of the non-volatile memory device for storing charges for a long period of time and thereby increasing the reliability of the non-volatile memory device.

In the fabricating method of the MOSFET with a thick gate dielectric layer disclosed by the invention, the floating gate can be electrically connected to a gate electrode, thus forming a metal-oxide-semiconductor (MOS) transistor having a thicker gate dielectric layer. Although the floating gate has already been electrically connected to a gate electrode, and thus not a non-volatile memory device any more, but simply an MOS transistor having four electrodes (the gate, the source, the drain and the substrate), since the MOS transistor has a thicker gate dielectric layer, the device can operate under a higher gate voltage and simultaneously provide suitable high-voltage devices to the general non-volatile memory that requires a higher operational voltage without additional high-voltage modules and an increased thermal budget derived from adding this embedded fabricating process.

In other words, the fabricating method of the MOSFET with a thick gate dielectric layer disclosed by the invention can generate a thicker floating gate dielectric layer so that the reliability of the non-volatile memory device for storing charges for a long period of time is improved. In the other aspect, the fabricating method also generates an even thicker gate dielectric layer than that of the original I/O transistor, which renders the new I/O transistor capable of withstanding higher operational voltages.

The fabricating method of the MOSFET with a thick gate dielectric layer of the invention also applies to a single-layered polysilicon floating gate technology (the non-volatile memory), and to some high-voltage operation requirements in the peripheral circuit under the general logic process, not limited to the fabricating technology of the single-layered polysilicon floating gate.

In order to make the aforementioned and other objects, features and advantages of the present invention more comprehensible, preferred embodiments accompanied with figures are described in detail below.

### BRIEF DESCRIPTION OF THE DRAWINGS

FIGS. 1A through 1F are cross-sectional views showing the flowcharts of fabricating a non-volatile memory according to one preferred embodiment of the present invention.

### DESCRIPTION OF EMBODIMENTS

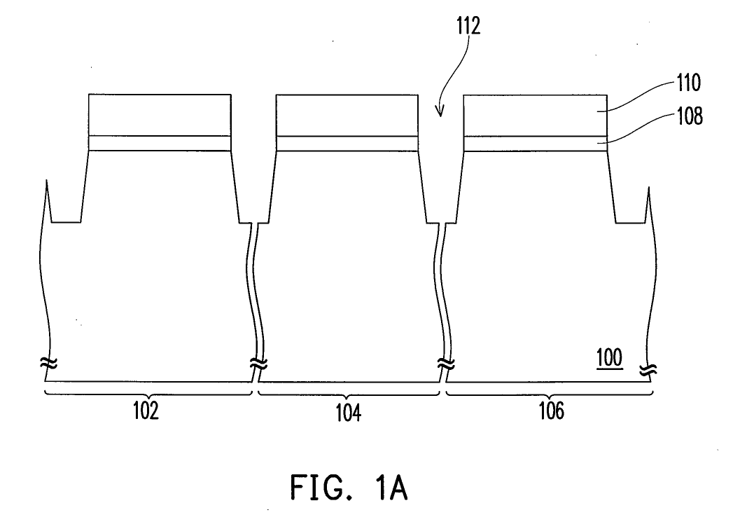

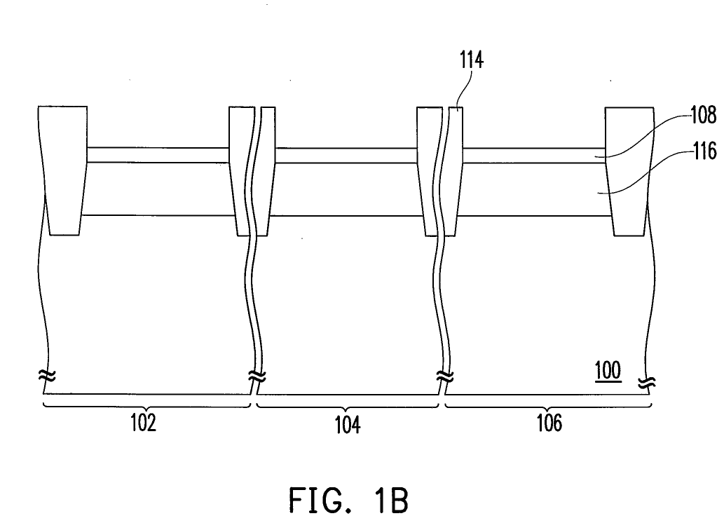

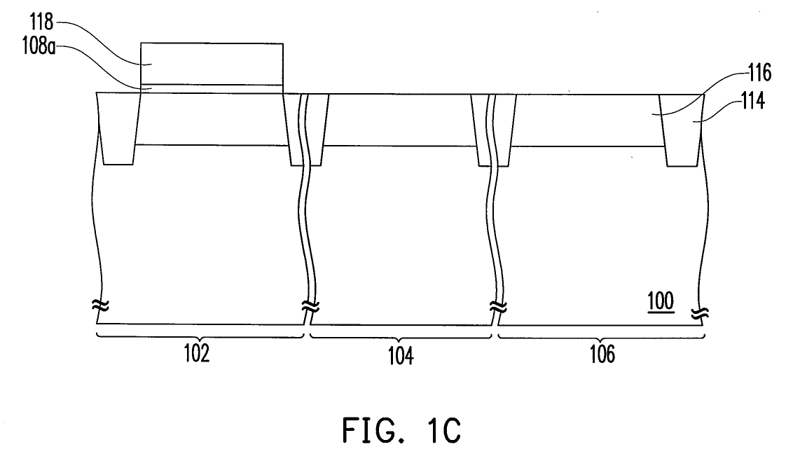

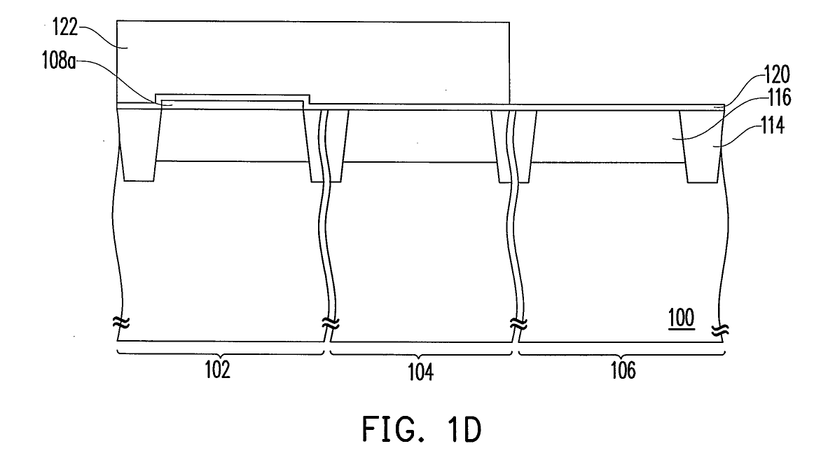

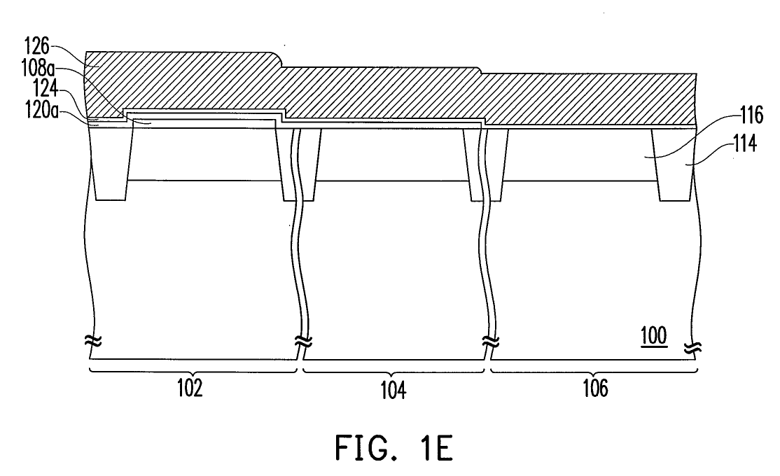

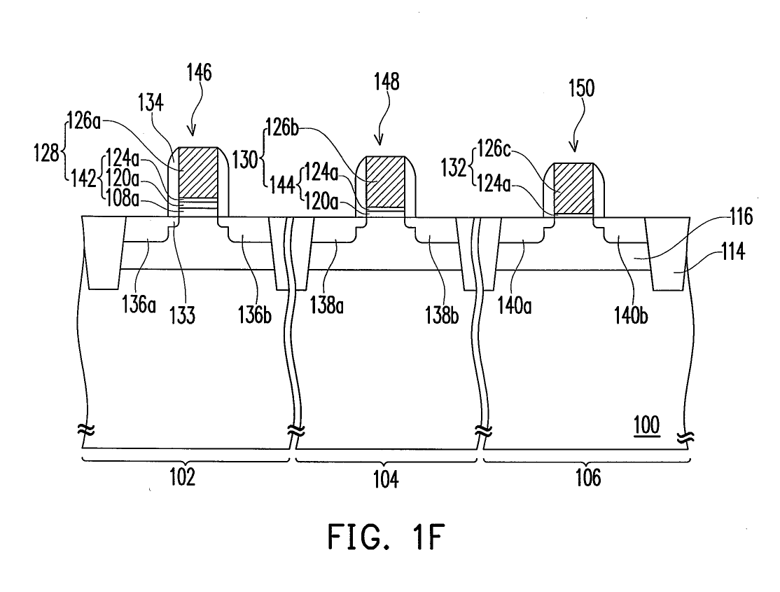

FIGS. 1A through 1F are cross-sectional views showing the flowcharts of fabricating a metal-oxide-semiconductor field effect transistor (MOSFET) with a thick gate dielectric layer according to one preferred embodiment of the present invention.

Referring to FIG. 1A, a substrate 100 is provided. The substrate 100 may be a silicon substrate. The substrate 100 may be divided into a first region 102, a second region 104 and a third region 106. The first region 102 may be a memory cell region. The second region 104 and the third region 106 may be peripheral circuit regions. The second region 104 and the third region 106 may be used to form input/output (I/O) or logic transistors with different voltage characteristics.

Afterwards, a pad layer 108 (insulating medium) is formed on the substrate 100. The material of the pad layer 108 may be silicon oxide. The method of forming the pad layer 108 may be a thermal oxidation process, and the thickness of the pad layer may be about 110 angstroms. Then, a masking layer 110 is formed on the substrate 100. The material of the masking layer 110 may be silicon nitride and the method of forming the masking layer 110 may be a chemical vapor deposition (CVD) process. Next, the masking layer 110 and the pad layer 108 are patterned. The masking layer 110 and the pad layer 108 may be patterned by performing a photolithographic and an etching processes. Afterwards, the patterned masking layer 110 is used as a mask to remove a portion of the substrate 100 so that a plurality of trenches 112 is formed in the substrate 100. The method of removing a portion of the substrate 100 includes performing a dry etching process such as a reactive ion etching process.

Referring to FIG. 1B, a plurality of isolation structures 114 is formed in the trenches 112 of the substrate 100. The isolation structures 114 may be formed, for example, by first forming an insulating layer (not shown) on the substrate 100 to fill the trenches 112. Then, a chemical mechanical polishing process is performed to remove the insulating layer outside of the trenches 112 using the masking layer 110 as a polishing stop layer.

Next, the masking layer 110 is removed. The method of removing the masking layer 110 includes performing a wet etching process, using a hot phosphoric acid solution as an etchant, for example. Then, a dopant implantation process is performed to form a well region 116 in the substrate 100. The method of implanting dopant in the substrate 100 may be an ion implantation process.

Referring to FIG. 1C, a patterned photoresist layer 118 is formed on the substrate 100. The patterned photoresist layer 118 covers the first region 102 so as to expose the pad layer 108 in the second region 104 and the third region 106. The patterned photoresist layer 118 may be formed by a photolithography process. Next, the pad layer 108 in the second region 104 and the third region 106 is removed using the patterned photoresist layer as a mask, wherein only a pad layer 108a in the first region 102 is retained. The method of removing the pad layer 108 in the second region 104 and the third region 106 includes performing a wet etching process, using a hydrofluoric acid as an etchant, for example. In the step of removing the pad layer 108 in the second region 104 and the third region 106, a portion of the isolation structures 114 are also removed altogether.

Referring to FIG. 1D, the patterned photoresist layer 118 is removed. The patterned photoresist layer 118 may be removed by performing an ashing process first to remove most of the photoresist layer and then performing a cleaning process to remove the remaining photoresist layer. In one embodiment, after removing the patterned photoresist layer 118, a rapid thermal annealing (RTA) process may be further performed to repair the exposed surface of the substrate 100 damaged by the etching process. Next, a dielectric layer 120 is formed on the substrate 100. The material of the dielectric layer 120 may be silicon oxide. The dielectric layer 120 may be formed by a thermal oxidation process or a chemical vapor deposition (CVD) process. The thickness of the dielectric layer 120 may be about 45 angstroms.

Afterwards, a patterned photoresist layer 122 is formed on the substrate 100. The patterned photoresist layer 118 covers the first region 102 and the second region 104 so as to expose the dielectric layer 120 on the third region 106. The patterned photoresist layer 122 may be formed by performing a photolithography process.

Referring to FIG. 1E, the dielectric layer 120 in the third region 106 is removed using the patterned photoresist layer 122 as a mask, wherein only a dielectric layer 120a in the first region 102 and the second region 104 is retained. The method of removing the dielectric layer 120 on the third region 106 includes performing a wet etching process, using a hydrofluoric acid as an etchant, for example. Next, the patterned photoresist layer 122 is removed. The patterned photoresist layer 122 may be removed by performing an ashing process first to remove most of the photoresist layer and then performing a cleaning process to remove the remaining photoresist layer.

In one embodiment, after removing the patterned photoresist layer 122, a rapid thermal annealing (RTA) process may be further performed to repair the exposed surface of the substrate 100 damaged by the etching process.

Next, a dielectric layer 124 is formed on the substrate 100. The material of the dielectric layer 124 may be silicon oxide. The dielectric layer 124 may be formed by a thermal oxidation process or a chemical vapor deposition (CVD) process and the thickness of the dielectric layer 124 may be about 20 angstroms.

Afterwards, a conductive layer 126 is formed over the whole substrate 100. The material of the conductive layer 126 may be doped polysilicon. The method of forming the conductive layer 126 may include forming an undoped polysilicon layer by a CVD process and then performing an ion implantation process. Alternatively, the conductive layer 126 may be formed by a CVD process with an in-situ dopant implantation.

Referring to FIG. 1F, the conductive layer 126, the dielectric layer 124, the dielectric layer 120a and the pad layer 108a are patterned to form a gate structure 128, a gate structure 130 and a gate structure 132 respectively on the first region 102, the second region 104 and the third region 106. The gate structure 128 may be constituted by a gate 126a and a tunneling dielectric layer 142. The tunneling dielectric layer 142 is constituted by a dielectric layer 124a, a dielectric layer 120a and a pad layer 108a. The gate structure 130 may be constituted by a gate 126b and a gate dielectric layer 144. The gate dielectric layer 144 is constituted by the dielectric layer 124a and the dielectric layer 120a. The gate structure 132 may be constituted by a gate 126c and the dielectric layer 124a. The dielectric layer 124a serves as a gate dielectric layer.

Next, a dopant implantation process is performed to form a lightly-doped region 133 in the substrate 100 at the two sides of the gate structure 128, the gate structure 130 and the gate structure 132 respectively.

Thereafter, insulating spacers 134 are formed respectively on the side walls of the gate structure 128, the gate structure 130 and the gate structure 132. The material of the insulating spacers 134 may be silicon oxide, silicon nitride, or SiON, for example. The insulating spacers 134 may be formed by performing a CVD process first to form an insulating material layer, and then a portion of the insulating material layer is removed by an anisotropic etching process.

Afterwards, a dopant implantation process is performed to form a source region 136a and a drain region 136b in the substrate 100 at the two sides of the gate structure 128, a source region 138a and a drain region 138b in the substrate 100 at the two sides of the gate structure 130, and a source region 140a and a drain region 140b in the substrate 100 at the two sides of the gate structure 132. The dopant implantation process includes steps such as implanting dopant in the substrate 100 by an ion implantation process. The gate structure 128, the source region 136a and the drain region 136b form a floating gate transistor 146. The gate structure 130, the source region 138a and the drain region 138b constitute an I/O transistor 148. The gate structure 132, the source region 140a and the drain region 140b constitute an I/O transistor 150. In one embodiment, after the source region 136a and the drain region 136b, the source region 138a and the drain region 138b, the source region 140a and the drain region 140b are respectively formed, the damaged surface of the substrate 100 caused by the implantation process can still be repaired by performing a rapid thermal annealing (RTA) process. The subsequent fabricating process of the memory is well known to those skilled in the art, and therefore is not to be reiterated herein.

In the abovementioned embodiment, since the tunneling dielectric layer 142 of the floating gate transistor 146 is constituted by the dielectric layer 124a, the dielectric layer 120a and the pad layer 108a and the thickness of the tunneling dielectric layer 142 may be larger than 110 angstroms, a better reliability for storing charges is obtained.

Moreover, in the foregoing embodiment, a portion of the pad layer 108a is retained as a portion of the tunneling dielectric layer 142. Hence, the floating gate transistor having the tunneling dielectric layer 142 with a larger thickness can be manufactured without changing the conditions of the fabricating process, particularly within the limits of the thermal budget of the whole fabricating process. This is because an insulating medium often exists in current advanced CMOS process, serving as a pad layer for STI module or a buffering dielectric layer for well implantation process to reduce the implant damage.

In addition, the damage done to the pad layer 108a during the removal of the masking layer 110 is also repaired when the dielectric layers 120 and 124 are growing at a high temperature or when the source/drain is formed by an annealing process.

The aforementioned embodiment takes the substrate 100 divided into three regions and the tunneling dielectric layer 142 constituted by the dielectric layer 124a, the dielectric layer 120a and the pad layer 108a as examples for illustration. Certainly, the substrate 100 may also be divided into two regions only, and the tunneling dielectric layer 142 may be constituted by just one dielectric layer and the pad layer 108a. Furthermore, the substrate 100 may also be divided into a plurality of regions, and the tunneling dielectric layer 142 may be constituted by more than two dielectric layers and the pad layer 108a.

Additionally, in the said embodiment, if a portion of the floating gate of the transistor 146 is electrically connected to the gate electrode in the first region 102, a transistor with a thicker gate oxide layer may also be thus formed. The transistor has the gate structure 128, the source region 136a and the drain region 136b that can be connected outward with 4 terminals' voltage, serve as an I/O transistor of the peripheral circuit and withstand a higher operational voltage. Thus, no additional high-voltage modules are required and the number of photomask procedures in the fabricating process of the embedded non-volatile memory is reduced thereby lowering the thermal budget derived from the additional high-voltage modules.

In summary, the fabricating method of the MOSFET with a thick gate dielectric layer disclosed by the invention increases the thickness of the tunneling dielectric layer of the floating gate transistor without raising the complexity and the thermal budget of the fabricating process thereby improving the reliability of the non-volatile memory device. In the other aspect, an I/O transistor having a thicker gate dielectric layer than that of the general peripheral circuit transistor can be formed so as to withstand greater operational voltages.

Although the present invention has been disclosed above by the preferred embodiments, they are not intended to limit the present invention. Anybody skilled in the art can make some modifications and alterations without departing from the spirit and scope of the present invention. Therefore, the protecting range of the present invention falls in the appended claims.

What is claimed is:

1. A fabricating method of an MOSFET with a thick gate dielectric layer, comprising:
providing a substrate having a first region and a second region, wherein a plurality of isolation structures has been formed therein, and an insulating medium serving as a pad layer for Shallow Trench Isolation module or a buffering layer for well implantation process and a masking layer are sequentially formed thereon between the isolation structures;
patterning the masking layer;
removing the insulating medium in the second region;
removing the masking layer;
forming a dielectric layer on the substrate;
forming a conductive layer on the substrate;
patterning the conductive layer, the dielectric layer and the insulating medium to form a first gate structure in the first region and a second gate structure in the second region; and
forming a first source region and a first drain region respectively in the substrate at the two sides of the first gate structure, and forming a second source region and a second drain region respectively in the substrate at the two sides of the second gate structure.

2. The fabricating method as claimed in claim 1, wherein the first region is a memory cell region and the second region is a peripheral circuit region.

3. The fabricating method as claimed in claim 2, wherein the first gate structure, the first source region and the first drain region constitute a floating gate transistor having the characteristics of a non-volatile memory, and the second gate structure, the second source region and the second drain region constitute either input/output (I/O) or logic transistor.

4. The fabricating method as claimed in claim 3, wherein the insulating medium and the dielectric layer constitute a tunneling dielectric layer of the floating gate transistor.

5. The fabricating method as claimed in claim 3, wherein the dielectric layer constitutes a gate dielectric layer of the I/O or logic transistor.

6. The fabricating method as claimed in claim 1, wherein the thickness of the dielectric layer is smaller than that of the insulating medium.

7. The fabricating method as claimed in claim 1, wherein the material of the conductive layer comprises doped polysilicon.

8. The fabricating method as claimed in claim 1, wherein the steps of removing the insulating medium in the second region comprise:
forming a patterned photoresist layer on the substrate to cover the first region; and
removing a portion of the insulating medium using the patterned photoresist layer as a mask.

9. The fabricating method as claimed in claim 1, wherein the material of the insulating medium comprises silicon oxide.

10. The fabricating method as claimed in claim 1, wherein the material of the dielectric layer comprises silicon oxide.

11. A fabricating method of an MOSFET with a thick gate dielectric layer, comprising:
providing a substrate having a first region, a second region and a third region, wherein a plurality of isolation structures has been formed therein and an insulating medium serving as a pad layer for STI module or a buffering layer for well implantation process and a masking layer are sequentially formed thereon between the isolation structures;
patterning the masking layer;
removing the insulating medium in the second and the third regions;
removing the masking layer;
forming a first dielectric layer on the substrate;
removing the first dielectric layer in the third region;
forming a second dielectric layer on the substrate;
forming a conductive layer on the substrate;
patterning the conductive layer, the second dielectric layer, the first dielectric layer and the insulating medium so as to form a first gate structure in the first region, a second gate structure in the second region and a third gate structure in the third region; and
forming a first source region and a first drain region respectively in the substrate at the two sides of the first gate structure, a second source region and a second drain region respectively in the substrate at the two sides of the second gate structure, and a third source region and a third drain region respectively in the substrate at the two sides of the third gate structure.

12. The fabricating method as claimed in claim 11, wherein the first gate structure, the first source region and the first drain region constitute a floating gate transistor having the characteristics of a non-volatile memory, the second gate structure, the second source region and the second drain region constitute a first input/output (I/O) transistor, and the third gate structure, the third source region and the third drain region constitute a second I/O transistor.

13. The fabricating method as claimed in claim 12, wherein the insulating medium, the first dielectric layer and the second dielectric layer constitute a tunneling dielectric layer of the floating gate transistor.

14. The fabricating method as claimed in claim 12, wherein the first dielectric layer and the second dielectric layer constitute a gate dielectric layer of the first I/O transistor.

15. The fabricating method as claimed in claim 12, wherein the second dielectric layer constitutes a gate dielectric layer of the second I/O transistor.

16. The fabricating method as claimed in claim 11, wherein the thickness of the second dielectric layer is smaller than that of the first dielectric layer, and the thickness of the first dielectric layer is smaller than that of the insulating medium.

17. The fabricating method as claimed in claim 11, wherein the material of the conductive layer comprises doped polysilicon.

18. The fabricating method as claimed in claim 11, wherein the steps of removing the insulating medium in the second and the third regions comprise:
forming a first patterned photoresist layer on the substrate to cover the first region; and
removing a portion of the exposed insulating medium using the patterned photoresist layer as a mask.

19. The fabricating method as claimed in claim 11, wherein the steps of removing the first dielectric layer in the third region comprise:
forming a second patterned photoresist layer on the substrate to cover the first and the second regions; and
removing a portion of the exposed first dielectric layer using the second patterned photoresist layer as a mask.

20. The fabricating method as claimed in claim 11, wherein the material of the insulating medium, the first dielectric layer and the second dielectric layer comprises silicon oxide.
